(19) United States
(12) Patent Application Publication
(10) Pub. No.: US 2025/0324862 A1
(43) Pub. Date: Oct. 16, 2025

(54) INVERSE TAPER OVERHANG

(71) Applicant: Applied Materials, Inc., Santa Clara, CA (US)

(72) Inventors: Chung-Chia CHEN, Hsinchu City (TW); Sheng-Wen WANG, Tainan City (TW); Ji Young CHOUNG, Hwaseong-si (KR); Yu-Hsin LIN, Zhubei City (TW); Jungmin LEE, Santa Clara, CA (US)

(21) Appl. No.: 19/176,434

(22) Filed: Apr. 11, 2025

Related U.S. Application Data
(60) Provisional application No. 63/633,457, filed on Apr. 12, 2024.

(51) Int. Cl. H10K 59/122; H10K 59/80; H10K 102/10

(52) U.S. Cl. CPC H10K 59/122; H10K 59/80521; H10K 59/873; H10K 2102/101

(57) ABSTRACT

In some embodiments, the present disclosure provides devices. The devices include a backplane. A plurality of overhang structures are disposed over the backplane. Each overhang structure is defined by a top extension of a top structure extending laterally past a bottom structure. The bottom structure is disposed over the backplane. Adjacent overhang structures of the plurality of overhang structures define a plurality of sub-pixels. The bottom structure includes a first sub-layer having a lower surface and an upper surface width, in which the first sub-layer is disposed over the backplane. A second sub-layer has a top surface width that is greater than a bottom surface width is disposed over the first sub-layer. Each sub-pixel includes an organic light-emitting diode (OLED) material is disposed under the adjacent overhang structures. A cathode is disposed over the OLED material and under the adjacent overhang structures.

### CROSS-REFERENCE TO RELATED APPLICATIONS

This application claims benefit of U.S. provisional patent application Ser. No. 63/633,457, filed Apr. 12, 2024. The aforementioned related patent application is herein incorporated by reference in its entirety.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and backplane on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and backplane size. Rather than utilizing a fine metal mask, photolithography should be used to pattern pixels. Accordingly, an improved sub-pixel circuits and methods of forming sub-pixel circuits in an OLED display are needed.

### SUMMARY

In some embodiments, the present disclosure provides devices. The devices include a backplane. A plurality of overhang structures are disposed over the backplane. Each overhang structure is defined by a top extension of a top structure extending laterally past a bottom structure. The bottom structure is disposed over the backplane. Adjacent overhang structures of the plurality of overhang structures define a plurality of sub-pixels. The bottom structure includes a first sub-layer having a lower surface and an upper surface width, in which the first sub-layer is disposed over the backplane. A second sub-layer has a top surface width that is greater than a bottom surface width is disposed over the first sub-layer. Each sub-pixel includes an organic light-emitting diode (OLED) material is disposed under the adjacent overhang structures. A cathode is disposed over the OLED material and under the adjacent overhang structures.

In other embodiments, the present disclosure provides devices. The devices include a backplane. A plurality of overhang structures are disposed over the backplane. Each overhang structure is defined by a top extension of a top structure extending laterally past a bottom structure. The bottom structure is disposed over the backplane. Adjacent overhang structures of the plurality of overhang structures define a plurality of sub-pixels. The bottom structure includes a first sub-layer having a lower surface and an upper surface width, in which the first sub-layer is disposed over the backplane. A second sub-layer has a top surface width that is greater than a bottom surface width is disposed over the first sub-layer. Each sub-pixel includes an organic light-emitting diode (OLED) material is disposed under the adjacent overhang structures. A cathode is disposed over the OLED material and under the adjacent overhang structures. An encapsulation layer is disposed over a first sidewall of the first sub-layer, a second sidewall of the second sub-layer, and a bottom surface of the top structure.

In other embodiments, the present disclosure provides devices. The devices include a backplane. A plurality of overhang structures are disposed over the backplane. Each overhang structure is defined by a top extension of a top structure extending laterally past a bottom structure. The bottom structure is disposed over the backplane. Adjacent overhang structures of the plurality of overhang structures define a plurality of sub-pixels. The bottom structure includes a top surface width that is greater than a bottom surface width. The bottom structure is disposed over the backplane. Each sub-pixel includes an organic light-emitting diode (OLED) material disposed over the backplane and under the adjacent overhang structures. A cathode is disposed over the OLED material and under the adjacent overhang structures.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit, according to embodiments.

FIG. 1B is a schematic, cross-sectional view of a sub-pixel circuit, according to embodiments.

FIG. 2 is a schematic, cross-sectional view of an overhang structure, according to embodiments.

FIG. 3 is a schematic, cross-sectional view of a tapered profile, according to embodiments.

FIG. 4A is a schematic, cross-sectional view of a sub-pixel circuit having a first sub-layer and a second sub-layer, according to embodiments.

FIG. 4B is a schematic, cross-sectional view of a sub-pixel circuit having a first sub-layer, according to embodiments.

FIG. 5 is a schematic, cross-sectional view of an overhang structure having a concentration gradient, according to embodiments.

FIGS. 6A and 6B are schematic, cross-sectional views of a backplane during a method for forming a sub-pixel circuit according embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display.

Each of the embodiments described herein of the sub-pixel circuit include a plurality of sub-pixels with each of the sub-pixels defined by adjacent overhang structures that are permanent to the sub-pixel circuit. While the Figures depict two sub-pixels with each sub-pixel defined by adjacent overhang structures, the sub-pixel circuit of the embodiments described herein include a plurality of sub-pixels, such as two or more sub-pixels. Each sub-pixel has the OLED material configured to emit a white, red, green, blue or other color light when energized, e.g., the OLED material of a first sub-pixel emits a red light when energized, the OLED material of a second sub-pixel emits a green light when energized, and the OLED material of a third sub-pixel emits a blue light when energized.

Currently, it is desirable, when OLED pixel patterning, to ensure cathodes contact each sidewall of an overhang structure. However, the cathode can be blocked by earlier deposited organic layers or can be too thin due to the overhang, thereby limiting the cathode contact. The overhang structures are permanent to the sub-pixel circuit and include a bottom structure having a tapered profile, e.g., a first sub-layer having a tapered sidewall disposed over a backplane and a second sub-layer having an inverse tapered sidewall disposed over the first sub-layer. The overhang structures include a top structure disposed over the bottom structure, the top structure is disposed over the second sub-layer to form an overhang structure. Adjacent overhang structures define each sub-pixel of the sub-pixel circuit of the display. Evaporation deposition is utilized for deposition of OLED materials (including a hole injection layer (HIL), a hole transport layer (HTL), an emissive layer (EML), and an electron transport layer (ETL)) and cathode. In one embodiment, cathode has greater conductivity than the OLED materials. In some instances, an encapsulation layer may be disposed via evaporation deposition.

The overhang structures and evaporation angle set by the evaporation source define the deposition angles, e.g., the overhang structures provide for a shadowing effect during evaporation deposition with the evaporation angle set by the evaporation source. Without being bound by theory, the overhang structures having a bottom structure having a tapered profile can allow for enhanced cathode contact along the sidewall of the first sub-layer and second sub-layer, thereby increasing device efficiency. Moreover, the overhang structures having a bottom structure having a tapered profile can further separate the deposited OLED material from the cathode, thereby reducing deposition angle complexity to ensure sufficient cathode contact. Additionally, the overhang structures having a bottom structure having a tapered profile can allow for enhanced cathode deposition control by adjusting one or more of the taper angle between the first sub-layer and the second sub-layer, the thickness ratio between the first sub-layer and the second sub-layer, and/or the depth of the overhang.

The overhang structures have a bottom structure having a tapered profile, which can allow for enhanced deposition of the encapsulation layer compared to conventional overhang structures. For example, the bottom structure includes a top surface width that is greater than a bottom surface width disposed over an upper surface of each PDL structures. In some embodiments, an assistant cathode layer is disposed between the bottom structure and the backplane and/or the PDL structures. As a further example, the tapered profile of the bottom structure can allow for deposition of the encapsulation layer to reduce and/or eliminate the formation of a cavity in the encapsulation layer under the overhang structure. Additionally, the encapsulation layer can include a controllable thickness, composition, and deposition method depending on the OLED materials deposited on the sub-pixels.

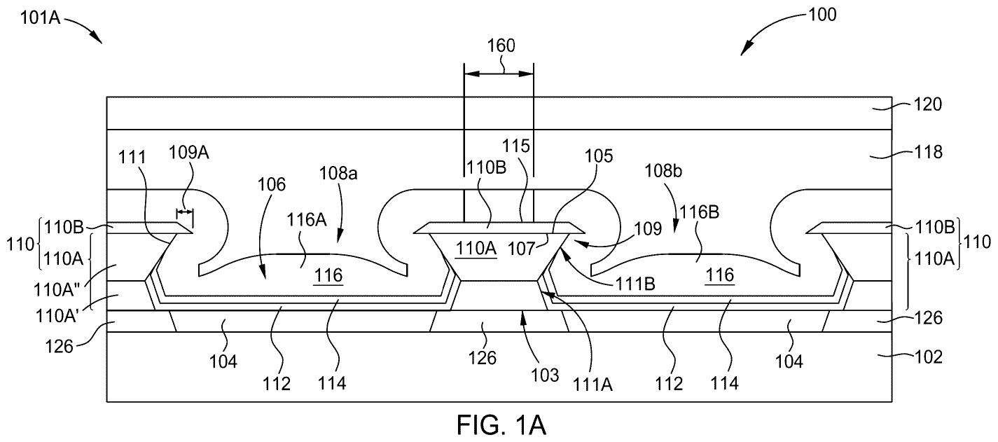

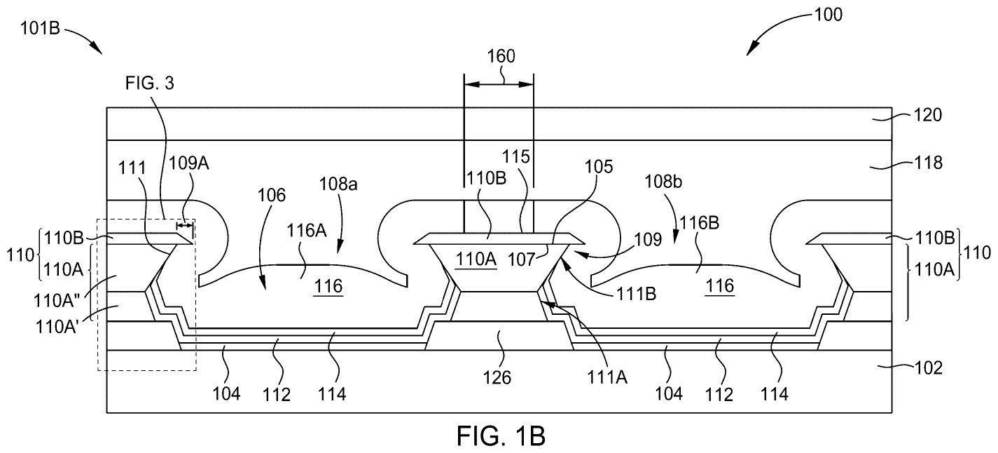

FIG. 1A is a schematic, cross-sectional view of a sub-pixel circuit 100 having an arrangement 101A. The sub-pixel circuit 100 includes a backplane 102. Metal-containing layers 104 may be patterned on the backplane 102 and are defined by adjacent pixel-defining layer (PDL) structures 126 disposed on the backplane 102. In one embodiment, the metal-containing layers 104 are pre-patterned on the backplane 102, e.g., a pre-patterned indium tin oxide (ITO) glass substrate. The metal-containing layers 104 are configured to operate anodes of respective sub-pixels. The metal-containing layers 104 can include titanium, gold, silver, copper, aluminum, ITO, IZO, or a combination thereof. In some embodiments, the metal-containing layer 104 is a layer stack of a first transparent conductive oxide (TCO) layer, a second metal-containing layer disposed on the first TCO layer, and a third TCO layer disposed on the second metal-containing layer.

The PDL structures 126 are disposed on the backplane 102. The PDL structures 126 include one of an organic material, an organic material with an inorganic coating disposed thereover, or an inorganic material. The organic material of the PDL structures 126 can include polyimides. The inorganic material of the PDL structures 126 can include silicon oxide (SiO₂), silicon nitride (Si₃N₄), silicon oxynitride (Si₂N₂O), magnesium fluoride (MgF₂), or combinations thereof. Adjacent PDL structures 126 define a respective sub-pixel and expose the anode (e.g., metal-containing layer 104) of the respective sub-pixel of the sub-pixel circuit 100.

The sub-pixel circuit 100 has a plurality of sub-pixels 106 including at least a first sub-pixel 108a and a second sub-pixel 108b. While the Figures depict the first sub-pixel 108a and the second sub-pixel 108b, the sub-pixel circuit 100 of the embodiments described herein may include two or more sub-pixels 106, such as a third, a fourth, and a fifth sub-pixel. Each sub-pixel 106 has an organic light-emitting diode (OLED) material 112 configured to emit a white, red, green, blue or other color light when energized, e.g., the OLED material 112 of the first sub-pixel 108a emits a red light when energized and the OLED material of the second sub-pixel 108b emits a green light when energized. The OLED material of a third sub-pixel, fourth sub-pixel, and/or fifth sub-pixel can emit a blue light or other color light when energized.

Overhang structures 110 are disposed over an upper surface 103 of each of the PDL structures 126. The overhang structures 110 are permanent to the sub-pixel circuit. The overhang structures 110 further define each sub-pixel 106 of the sub-pixel circuit 100. The overhang structures 110 include at least a top structure 110B disposed over a bottom structure 110A. In one embodiment, the top structure 110B is disposed on the bottom structure 110A. The bottom structure 110A is disposed over the upper surface 103 of the PDL structure 126. In one embodiment, the bottom structure 110A is disposed on the upper surface 103 of the PDL structure 126. Each overhang structure 110 includes adjacent overhangs 109. The adjacent overhangs 109 are defined by a top extension 109A of the top structure 110B extending laterally past a sidewall 111 of the bottom structure 110A.

The top structure 110B includes one of an inorganic material or metal-containing material. The inorganic material includes, but it not limited to, an inorganic silicon-containing material, e.g., oxides or nitrides of silicon, or combinations thereof. In some embodiments, the inorganic materials of the top structure 110B include silicon nitride (Si₃N₄), silicon oxide (SiO₂), silicon oxynitride (Si₂N₂O), or combinations thereof. The metal-containing materials include at least one of a metal or metal alloy such as titanium (Ti), aluminun (Al), aluminum neodymium (AlNd), molybdenum (Mo), molybdenum tungsten (MoW), copper (Cu), or combinations thereof. In some embodiments, the metal-containing materials include a transparent conductive oxide (TCO) such as indium tin oxide or indium zinc oxide. The inorganic material may be conductive or non-conductive. In some embodiments, the top structure 110B includes a non-conductive inorganic material and the bottom structure 110A includes a conductive inorganic material or a metal-containing material. In another example, the top structure 110B includes a conductive inorganic material or metal-containing material and the bottom structure 110A includes a conductive inorganic material or metal-containing material.

The bottom structure 110A includes a first sub-layer 110A′. The first sub-layer 110A′ is disposed over the backplane 102. The first sub-layer 110A′ has a lower surface and an upper surface. In some embodiments, the width of the upper surface is greater than the width of the lower surface.

The first sub-layer 110A′ can include a conductive material or inorganic material. The inorganic material can include an inorganic silicon-containing material, e.g., oxides or nitrides of silicon, or combinations thereof. The inorganic materials of the first sub-layer 110A′ and the top structure 110B include silicon nitride (Si₃N₄), silicon oxide (SiO₂), silicon oxynitride (Si₂N₂O), or combinations thereof. The conductive materials include at least one of a metal or metal alloy, e.g., a transparent conducting oxide. The metal includes titanium (Ti), aluminun (Al), aluminum neodymium (AINd), molybdenum (Mo), molybdenum tungsten (MoW), copper (Cu), indium tin oxide (ITO), indium zinc oxide (IZO), or combinations thereof. The metal alloy includes an alloy of the metal. In some embodiments, an assistant cathode layer is disposed between the first sub-layer 110A′ and the backplane 102 and/or the PDL structures 126. The bottom structure 110A includes a second sub-layer 110A″. The second sub-layer 110A″ is disposed over the first sub-layer 110A′. The second sub-layer 110A″ has a top surface and a bottom surface. In some embodiments, the width of the top surface is greater than the width of the bottom surface.

The second sub-layer 110A″ can include a conductive material such as a metal-containing material. The metal-containing materials include at least one of a metal or metal alloy such as titanium (Ti), indium tin oxide (ITO), indium zinc oxide (IZO), aluminum (Al), aluminum neodymium (AINd), molybdenum (Mo), molybdenum tungsten (MoW), copper (Cu), or combinations thereof. For example, the first sub-layer 110A′ includes a non-conductive inorganic material and the second sub-layer 110A″ includes a conductive inorganic material or a metal-containing material.

The first sub-layer 110A′ may include the same or a different material from the second sub-layer 110A″. In some embodiments, the first sub-layer 110A′ includes a metal and the second sub-layer 110A″ includes a metal. In these embodiments, the first sub-layer 110A′ may include molybdenum and the second sub-layer 110A″ may include aluminum. In other embodiments, the first sub-layer 110A′ may include molybdenum and the second sub-layer 110A″ may also include molybdenum.

In some embodiments, the first sub-layer 110A′ includes a metal and the second sub-layer 110A″ includes a transparent conductive oxide. In these embodiments, the first sub-layer 110A′ may include molybdenum and the second sub-layer 110A″ may include indium zinc oxide. In some embodiments, the first sub-layer 110A′ includes a transparent conductive oxide and the second sub-layer 110A″ includes a metal. In these embodiments, the first sub-layer 110A′ may include indium zinc oxide and the second sub-layer 110A″ may include molybdenum.

In some embodiments, the first sub-layer 110A′ includes a transparent conductive oxide and the second sub-layer 110A″ includes a transparent conductive oxide. In these embodiments, the first sub-layer 110A′ may include indium zinc oxide and the second sub-layer 110A″ may include indium tin oxide. In other embodiments, the first sub-layer 110A′ may include indium zinc oxide and the second sub-layer 110A″ may also include indium zinc oxide.

The bottom structure 110A includes a taper profile. For example. at least a lower surface of the first sub-layer 110A′ is wider than an upper surface of the first sub-layer 110A′, at least a top surface of the second sub-layer 110A″ is wider than a bottom surface of the second sub-layer 110A″ (as shown in FIG. 1A and 1B). As a further example, the taper profile can include a first sub-layer 110A′, having a first sidewall 111A, that extends toward a central portion of the top structure 110B, while the second sub-layer 110A″, having a second sidewall 111B, that extends toward a lateral portion of the top structure 110B. Without being bound by theory, a bottom structure 110A having a taper profile can allow for increased cathode contact with the conducting material of the second sub-layer 110A″.

Adjacent overhangs 109 are defined by the top extension 109A of the top structure 110B. At least a bottom surface 107 of the top structure 110B is wider than a top surface 105 of the bottom structure 110A to form the top extension 109A (as shown in FIG. 1A and 1B) of the overhang 109. The top structure 110B is disposed over a top surface 105 of the bottom structure 110A, e.g., a top surface of the second sub-layer 110A″. The top extension 109A of the top structure 110B forms the overhang 109 and allows for the top structure 110B to shadow the bottom structure 110A. The shadowing of the overhang 109 provides for evaporation deposition of each of the OLED material 112 and a cathode 114. The OLED material 112 is disposed under the overhang 109. The cathode 114 is disposed over the OLED material 112 and extends under the overhang 109. In an embodiment, the OLED material is disposed over first sidewall 111A of the first sub-layer 110A′. In one embodiment, as shown in FIG. 1A and 1B, the cathode 114 is disposed over the OLED material such that the cathode 114 contacts the second side wall 111B of the second sub-layer 110A″.

The overhang structures 110 and an evaporation angle set by an evaporation source define deposition angles, e.g., the overhang structures 110 provide for a shadowing effect during evaporation deposition with the evaporation angle set by the evaporation source. The overhang 109 and the evaporation source define an OLED angle θ_{OLED} of the OLED material 112 and a cathode angle θ_{cathode} of the cathode 114 (shown in FIG. 2). The OLED angle θ_{OLED} of the OLED material 112 and the cathode angle θ_{cathode} of the cathode 114 result from the overhang structures 110 and the evaporation angle set by the evaporation source. In some embodiments, the overhang structures 110 provide for a shadowing effect during evaporation deposition of the OLED material 112 and the cathode 114 with the evaporation angle set by the evaporation source.

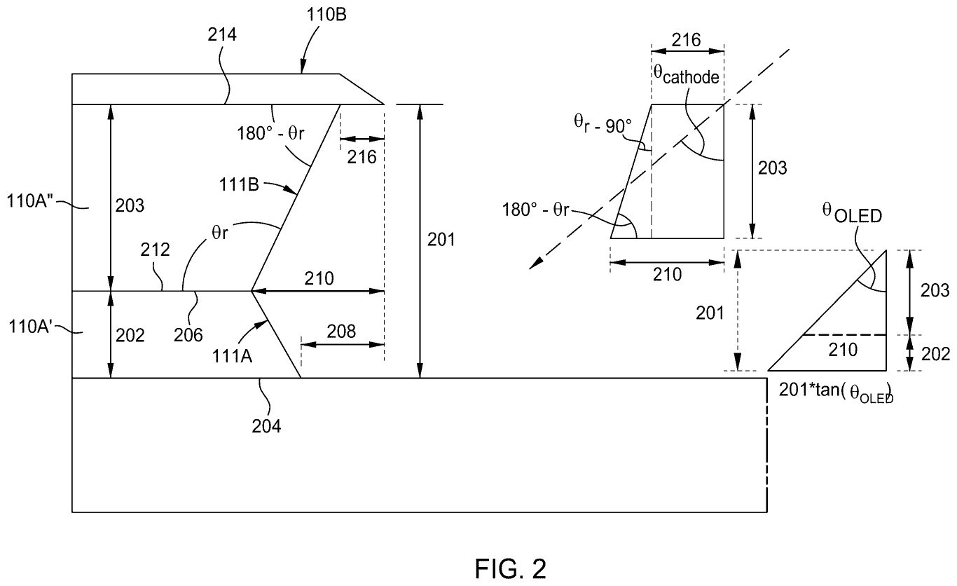

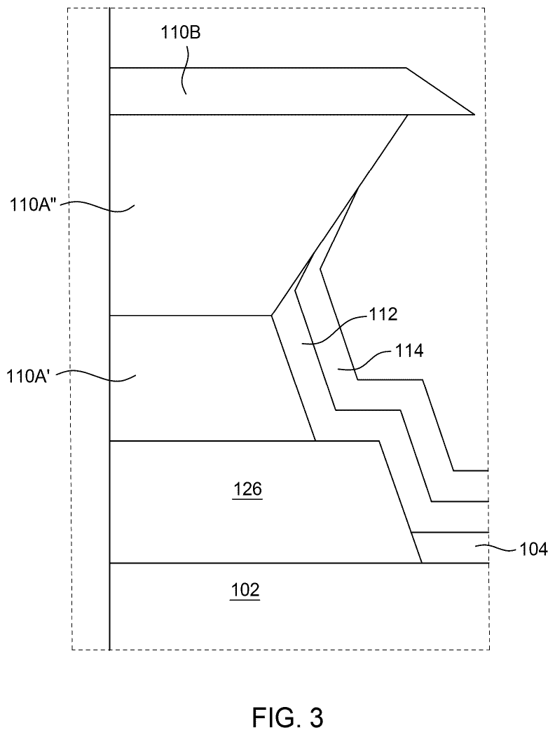

In some embodiments, the OLED material 112 contacts the first sidewall 111A of the first sub-layer 110A′, and the cathode 114 contacts the second sidewall 111B of the second sub-layer 110A″ of the bottom structure 110A of the overhang structures 110, as shown in FIG. 3. In another embodiment, the cathode 114 contacts the first sidewall 111A of the first sub-layer 110A′ of the bottom structure 110A of the overhang structures 110. In another embodiment, the cathode 114 contacts the second sidewall 111B of the second sub-layer 110A″ of the bottom structure 110A of the overhang structures 110.

In some embodiments, as shown in FIG. 1A, the encapsulation layer 116 is disposed over the first sidewall 111A and the second sidewall 111B of the bottom structure 110A and a bottom surface 107 of the top structure 110B. In another embodiment, the cathode 114 contacts busbars (not shown) outside of an active area of the sub-pixel circuit 100. The cathode 114 includes a conductive material, such as a metal or metal alloy, e.g., chromium, titanium, aluminum, ITO, IZO, silver, magnesium, or a combination thereof. In some embodiments, the material of the cathode 114 is different from the material of the bottom structure 110A and the top structure 110B.

Each sub-pixel 106 includes an encapsulation layer 116, e.g., the first sub-pixel 108a has a first encapsulation layer 116A and the second sub-pixel 108b has a second encapsulation layer 116B. The encapsulation layer 116 may be or may correspond to a local passivation layer. The encapsulation layer 116 of a respective sub-pixel is disposed over the cathode 114 (and OLED material 112) with the encapsulation layer 116 extending under the overhang structures 110 and over the first sidewall 111A and second side wall 111B of each of the overhang structures 110. In one embodiment, as shown in sub-pixels 108a and 108b of FIG. 1A, the first encapsulation layer 116A and second encapsulation layer 116B are disposed over the cathode 114 and extends under the adjacent overhangs 109 and contacts a bottom surface 107 of the top structure 110B, thereby filling and/or sealing a cavity formed under the bottom surface 107 of the top structure 110B.

In some embodiments, the portion of the top surface 115 of the top structure 110B that the first encapsulation layer 116A is disposed over is separated from the portion of the top surface 115 of the top structure 110B that the second encapsulation layer 116B is disposed over. A space 160 therefore exists between the first encapsulation layer 116A and the second encapsulation layer 116B, as shown in FIG. 1A. In some embodiments, the space 160 extends along the entire top surface 115, such that the first encapsulation layer 116A and the second encapsulation layer 116B are not disposed over the top surface 115. In some embodiments, the first encapsulation layer 116A overlaps with the second encapsulation layer 116B.

In embodiments including one or more capping layers, the capping layers are disposed between the cathode 114 and the encapsulation layer 116, e.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. In another embodiment, the sub-pixel circuit 100 further includes at least a global passivation layer 120 disposed over the overhang structure 110 and the encapsulation layer 116. In yet another embodiment, the sub-pixel includes an intermediate passivation layer 118 disposed over the overhang structures 110 of each of the sub-pixels 106, and disposed between the encapsulation layer 116 and the global passivation layer 120.

The arrangement 101A and 101B of the sub-pixel circuit 100 can further include at least a global passivation layer 120 disposed over the overhang structures 110 and the encapsulation layers 116. In one embodiment, an intermediate layer 118 may be disposed between the global passivation layer 120 and the overhang structures 110 and the encapsulation layers 116. The intermediate layer 118 may include an inkjet material, such as an acrylic material.

FIG. 1B is a schematic, cross-sectional view of a sub-pixel circuit 100 having an arrangement 101B. The sub-pixel circuit 100 includes a backplane 102. Metal-containing layers 104 may be patterned over the backplane 102 and are defined by overhang structures 110 disposed on the backplane 102. In one embodiment, the metal-containing layers 104 are pre-patterned on the backplane 102, e.g., a pre-patterned indium tin oxide (ITO) glass substrate. The metal-containing layers 104 are configured to operate anodes of respective sub-pixels. The metal-containing layers 104 can include titanium, gold, silver, copper, aluminum, ITO, IZO, or a combination thereof. In some embodiments, the metal-containing layer 104 is a layer stack of a first transparent conductive oxide (TCO) layer, a second metal-containing layer disposed on the first TCO layer, and a third TCO layer disposed on the second metal-containing layer.

The sub-pixel circuit 100 has a plurality of sub-pixels 106 including at least a first sub-pixel 108a and a second sub-pixel 108b. While the Figures depict the first sub-pixel 108a and the second sub-pixel 108b, the sub-pixel circuit 100 of the embodiments described herein may include two or more sub-pixels 106, such as a third, a fourth, and a fifth sub-pixel. Each sub-pixel 106 has an organic light-emitting diode (OLED) material 112 configured to emit a white, red, green, blue or other color light when energized, e.g., the OLED material 112 of the first sub-pixel 108a emits a red light when energized and the OLED material of the second sub-pixel 108b emits a green light when energized. The OLED material of a third sub-pixel, fourth sub-pixel, and/or fifth sub-pixel can emit a blue light or other color light when energized.

Overhang structures 110 are disposed over the backplane 102. The overhang structures 110 define each sub-pixel 106 of the sub-pixel circuit 100. The overhang structures 110 include at least a top structure 110B disposed over a bottom structure 110A, as described herein. In one embodiment, the top structure 110B is disposed on the bottom structure 110A. The bottom structure 110A is disposed over the backplane 102. Each overhang structure 110 includes adjacent overhangs 109. The adjacent overhangs 109 are defined by a top extension 109A of the top structure 110B extending laterally past a sidewall 111 of the bottom structure 110A.

FIG. 2 shows a schematic, cross-sectional view of an overhang structure 110. The overhang structure 110 can include a bottom structure 110A. The bottom structure 110A having a first sub-layer 110A′ and a second sub-layer 110A″. The bottom structure 110A includes a thickness 201. The thickness 201 can include the thickness of a first sub-layer thickness 202 and a second sub-layer thickness 203. In some embodiments, the first sub-layer thickness 202 can be from about 0.1 μm to about 0.8 μm, e.g., about 0.1 μm to about 0.4 μm, about 0.2 μm to about 0.4 μm, or about 0.3 μm to about 0.4 μm. In some embodiments, the second sub-layer thickness 203 can be from about 0.1 μm to about 0.8 μm, e.g., about 0.4 μm to about 0.7 μm, about 0.5 μm to about 0.7 μm, or about 0.5 μm to about 0.6 μm. In some embodiments, a second sub-layer thickness 203 that is greater than the thickness of the first sub-layer thickness 202. Without being bound by theory, one or more of a thickness ratio between the second sub-layer thickness 203 and the first sub-layer thickness 202, the deposition angle, the overhang depth, and the waist angle, can direct the OLED material to deposit on the first sub-layer 110A′, as described below, while allowing the cathode to deposit on the first sub-layer 110A′ and the second sub-layer 110A″, as shown in FIG. 3.

In some embodiments, the first sub-layer 110A′ has a lower surface 204 that is wider than an upper surface 206. In some embodiments, the lower surface 204 extends towards the sub-pixel to produce a lower surface gap 208. The lower surface gap 208 is the gap between the bottom lateral most edge of the first sub-layer 110A′ relative to the bottom lateral most edge of the top structure 110B. Without being bound by theory, a lower surface gap 208 that is reduced can prevent PDL damage, can improve cathode contact on the bottom structure 110A, and can promote encapsulation layer 116 closure, thereby sealing a cavity and/or preventing the formation of the cavity under the adjacent overhangs 109.

In some embodiments, the upper surface 206 extends towards the sub-pixel to produce a waist gap 210. The waist gap 210 is the gap between the top lateral most edge of the first sub-layer 110A′ and/or the bottom lateral most edge of the second sub-layer 110A″ relative to the bottom lateral most edge of the top structure 110B. In some embodiments, the second sub-layer 110A″ has a bottom surface 212 and a top surface 214. In some embodiments, the top surface 214 is wider than the bottom surface 212. Without being bound by theory, a top surface 214 that is wider than the bottom surface 212 can provide increased deposition of the cathode 114 on the bottom structure 110A. In some embodiments, the top surface 214 extends towards the sub-pixel to produce a top surface gap 216. The top surface gap 216 is the gap between the top lateral most edge of the second sub-layer 110A″ relative to the bottom lateral most edge of the top structure 110B. Without being bound by theory, a top surface gap 216 that is reduced can improve cathode contact on the bottom structure 110A, and can promote encapsulation layer 116 closure, thereby sealing a cavity and/or preventing the formation of the cavity under the adjacent overhangs 109.

In some embodiments, first sub-layer thickness 202 may be equal to the thickness 201 minus the second sub-layer thickness 203. In some embodiments, the first sub-layer thickness 202 may be greater than the quotient of the difference between the thickness 201 and the waist gap 210 divided by the tangent of the OLED angle θ_{OLED} of the OLED material 112.

In some embodiments, the second sub-layer 110A″ may include a second sidewall 111B, as described above. The second side wall 111B may extend from the bottom surface 212 towards the top structure 110B at a waist angle, θᵣ. In some embodiments, the waist angle, θᵣ, is greater than 90°. In some embodiments, the second side wall 111B may intersect the top structure 110B, in which the second side wall 111B forms an angle 180°−θᵣ when intersecting the top structure 110B. In some embodiments, the waist angle, θᵣ, minus 90° is less than the cathode angle θ_{cathode} of the cathode 114. In some embodiments, the second sub-layer thickness 203 multiplied by the tangent of the cathode angle θ_{cathode} of the cathode 114 is greater than the waist gap 210. In some embodiments, the cathode angle θ_{cathode} of cathode 114 is greater than the difference between the waist angle, θᵣ, and 90°, which is greater than the OLED angle θ_{OLED} of the OLED material 112. In some embodiments, the OLED angle θ_{OLED} of the OLED material 112 is about 40°. Without being bound by theory, θ_{cathode}>θᵣ−90°>θ_{OLED}, may increase deposition thickness of the cathode along the bottom structure 110A.

In some embodiments, the OLED material 112 contacts the first sidewall 111A of the first sub-layer 110A′, in which the OLED material 112 is partially deposited on the second sidewall 111B of the second sub-layer 110A″, as shown in FIG. 3. In some embodiments, the cathode 114 is deposited over the OLED material 112 and over a remaining portion of the second sidewall 111B of the second sub-layer 110A″ of the bottom structure 110A of the overhang structures 110. Without being bound by theory, the tapered profile of the overhang structures 110 can allow for improved cathode contact on the second sidewall 111B.

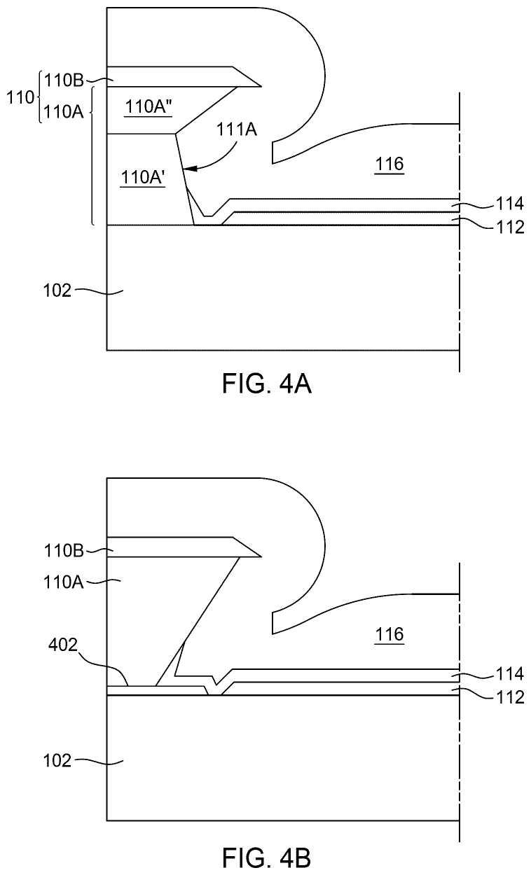

In some embodiments, the OLED material 112 does not contact the first sidewall 111A of the first sub-layer 110A′, as shown in FIG. 4A. In some embodiments, an assistant electrode 402 can be disposed between the backplane 102 and the overhang structure 110, as shown in FIG. 4B. In some embodiments, the cathode 114 is deposited over the OLED material 112 and over the first sidewall 111A of the first sub-layer 110A′, as shown in FIG. 4B. In some embodiments, the cathode 114 is deposited over the OLED material 112 and over the first sidewall 111A of the first sub-layer 110A′ and the second sidewall 111B of the second sub-layer 110A″ of the bottom structure 110A of the overhang structures 110. Without being bound by theory, the tapered profile of the overhang structures 110 can allow for improved cathode contact on the second sidewall 111B as well as improved encapsulation layer 116 closure.

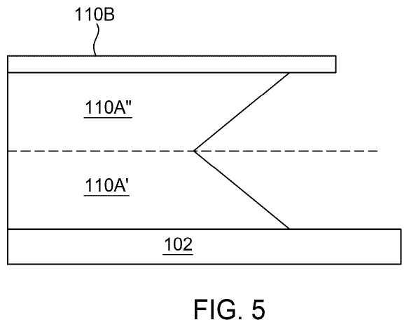

FIG. 5 is a schematic, cross-sectional view of an overhang structure having a concentration gradient. The concentration gradient may increase either linearly or differentially. In some embodiments, the concentration gradient increases towards the top structure 110B as shown in FIG. 5. For example, the first sub-layer 110A′ can include one or more of a metal, e.g., titanium (Ti), aluminum (Al), aluminum neodymium (AlNd), molybdenum (Mo), molybdenum tungsten (MoW), copper (Cu), or combinations thereof, and/or a metal containing oxide, e.g., indium tin oxide (ITO) or indium zinc oxide (IZO). In some embodiments, the first sub-layer 110A′ can be a TCO or IZO and can be produced using a PVD deposition using a partial pressure of oxygen of about 3%. The partial pressure of oxygen can increase during the deposition according to a concentration gradient in the second sub-layer 110A″. In some embodiments, the concentration gradient can include increasing the partial pressure of oxygen from about 3% to about 15%. For example, the partial pressure of oxygen during the PVD deposition can be about 15% where the second sub-layer 110A″ contacts the top structure 110B. Without being bound by theory, a higher partial pressure of oxygen can increase the etch resistivity, thereby allowing the waist gap to form due to the lower partial pressure of oxygen at the first sub-layer 110A′. Moreover, and without being bound by theory, the higher partial pressure of oxygen portion, e.g., the second sub-layer 110A″, can have less etching depth, thus forming the inverse taper design.

In some embodiments, the concentration gradient changes differentially such that the change in concentration near the upper surface is greater than the change in concentration near the lower surface. Alternatively, in some embodiments, the concentration gradient changes differentially such that the change in concentration near the upper surface is less than the change in concentration near the lower surface. In some embodiments, the concentration gradient changes differentially such that the change in concentration near the lower surface of upper surface is different than the change in concentration near the middle.

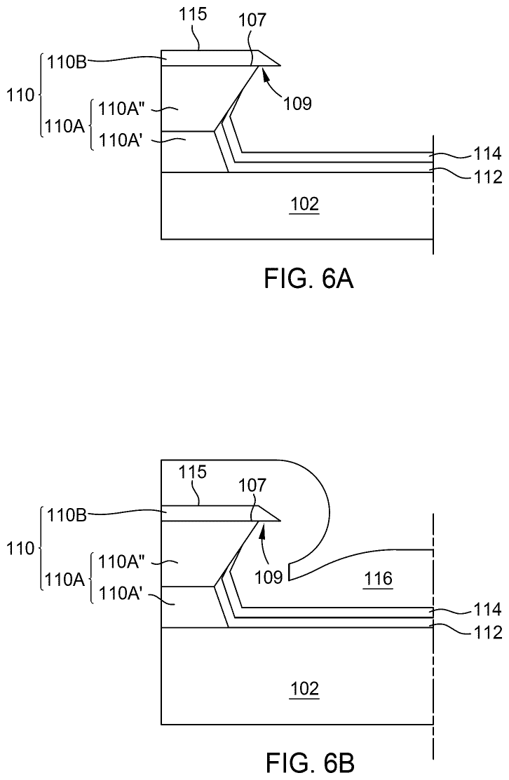

As shown in FIG. 6A, the OLED material 112 of the first sub-pixel 108a, and the cathode 114 are deposited. In some embodiments, the shadowing effect of the overhang structures 110 define the OLED angle θ_{OLED} (shown in FIG. 2) of the OLED material 112 and the cathode angle θ_{cathode} (shown in FIG. 2) of the cathode 114. The OLED angle θ_{OLED} of the OLED material 112 and the cathode angle θ_{cathode} of the cathode 114 result from evaporation deposition of the OLED material 112 and the cathode 114. In one embodiment, the cathode 114 contacts the bottom structure 110A of the overhang structures 110.

The encapsulation layer 116 is deposited over the cathode 114 (and the OLED material 112), as shown in FIG. 6B. In some embodiments including capping layers, the capping layers are deposited between the cathode 114 and the encapsulation layer 116. The capping layers may be deposited by evaporation deposition. The encapsulation layer 116 is deposited over the cathode 114. The encapsulation layer 116 of sub-pixel 108a can fill and/or seal one or more cavities under the adjacent overhangs 109, such that the encapsulation layer 116 can seal and/or block entrance to a cavity under the adjacent overhangs 109. In some embodiments, the encapsulation layer 116 of subpixel 108 contacts the bottom structure 110A, a bottom surface 107 of the top structure 110B, and a top surface 115 of the top structure 110B, thereby preventing a cavity and/or gap from forming under the adjacent overhangs 109.

In some embodiments, the OLED, cathode, and encapsulation layer may be deposited to form the sub-pixel circuit 100 including two or more sub-pixels 106, in which the deposition of the OLED, cathode, and encapsulation layer may be repeated for each addition sub-pixel, e.g. for a third and/or a fourth sub-pixel.

In summation, described herein are device relate to sub-pixel circuits and methods of forming sub-pixel circuits that may be utilized in a display such as an organic light-emitting diode (OLED) display. The overhang structures having a tapered profile can allow for greater cathode contact along the sidewall of the first sub-layer and second sub-layer, thereby increasing device efficiency. Moreover, the overhang structures having a tapered profile can further separate the deposited OLED material from the cathode, thereby reducing deposition angle complexity to ensure sufficient cathode contact. Additionally, the overhang structures having a tapered profile can allow for enhanced cathode deposition control by adjusting one or more of the taper angle between the first sub-layer and the second sub-layer, the ratio between the first sub-layer and the second sub-layer, and/or the depth of the overhang over the bottom layer having the tapered profile. Additionally, the overhang structures having a tapered profile can allow for enhanced deposition of the encapsulation layer, thereby eliminating the formation of a cavity and/or sealing a formed cavity in the encapsulation layer under the overhang structure.

While the foregoing is directed to embodiments of the present disclosure, other and further embodiments of the disclosure may be devised without departing from the basic scope thereof, and the scope thereof is determined by the claims that follow.

What is claimed is:

1. A device, comprising:
a backplane;
a plurality of overhang structures disposed over the backplane, each overhang structure defined by a top extension of a top structure extending laterally past a bottom structure, the bottom structure disposed over the backplane, adjacent overhang structures of the plurality overhang structures defining a plurality of sub-pixels, wherein the bottom structure comprises:
a first sub-layer, having a lower surface and an upper surface width, disposed over the backplane; and
a second sub-layer, having a top surface width that is greater than a bottom surface width, disposed over the first sub-layer;
each sub-pixel comprising:
an organic light-emitting diode (OLED) material disposed under the adjacent overhang structures; and
a cathode disposed over the OLED material and under the adjacent overhang structures.

2. The device of claim 1, wherein the top extension extends laterally past the second sub-layer.

3. The device of claim 1, further comprising an encapsulation layer disposed over a first sidewall of the first sub-layer, a second sidewall of the second sub-layer, and a bottom surface of the top structure.

4. The device of claim 1, wherein the first sub-layer comprises a non-conductive material or a conductive material and the second sub-layer comprises a conductive material.

5. The device of claim 4, wherein the first sub-layer comprises an inorganic material.

6. The device of claim 5, wherein the first sub-layer comprises one or more of silicon nitride (Si₃N₄), silicon oxide (SiO₂), or silicon oxynitride (Si₂N₂O).

7. The device of claim 4, wherein the second sub-layer comprises a metal-containing material.

8. The device of claim 7, wherein the second sub-layer comprises one or more of titanium (Ti), indium tin oxide (ITO), indium zinc oxide (IZO), aluminun (Al), aluminum neodymium (AlNd), molybdenum (Mo), molybdenum tungsten (MoW), copper (Cu), or a combination thereof.

9. The device of claim 4, wherein the first sub-layer comprises a metal-containing material and the second sub-layer comprises a metal-containing material.

10. The device of claim 4, wherein the first sub-layer comprises a metal-containing layer and the second sub-layer comprises a transparent conductive oxide.

11. The device of claim 4, wherein the first sub-layer comprises a transparent conductive oxide and the second sub-layer comprises a transparent conductive oxide.

12. The device of claim 1, wherein:
the OLED material is disposed over and in contact with the first sub-layer; and
the cathode is disposed over the OLED material and in contact with the second sub-layer.

13. The device of claim 1, further comprising an assistant electrode disposed between the backplane and the plurality of overhang structures.

14. A device, comprising:
a backplane;
a plurality of overhang structures disposed over the backplane, each overhang structure defined by a top extension of a top structure extending laterally past a bottom structure, the bottom structure disposed over the backplane, adjacent overhang structures of the plurality overhang structures defining a plurality of sub-pixels, wherein the bottom structure comprises:
a first sub-layer, having a lower surface width and an upper surface width, disposed over the backplane; and
a second sub-layer, having a top surface width that is greater than a bottom surface width, disposed over the first sub-layer;
each sub-pixel comprising:
an organic light-emitting diode (OLED) material disposed and under the adjacent overhang structures;
a cathode disposed over the OLED material and under the adjacent overhang structures; and
an encapsulation layer disposed over a first sidewall of the first sub-layer, a second sidewall of the second sub-layer, and a bottom surface of the top structure.

15. The device of claim 14, wherein the top extension extends laterally past the second sub-layer.

16. The device of claim 14, wherein the encapsulation layer comprises a silicon nitride material, silicon oxynitride material, silicon oxide material, or a combination thereof.

17. The device of claim 14, wherein:
the OLED material is disposed over and in contact with the first sub-layer; and
the cathode is disposed over the OLED material and in contact with the second sub-layer.

18. A device, comprising:
a backplane;
a plurality of overhang structures, each overhang structure defined by a top extension of a top structure extending laterally past a bottom structure, the bottom structure disposed over the backplane, adjacent overhang structures of the plurality overhang structures defining a plurality of sub-pixels, wherein the bottom structure comprises a top surface width that is greater than a bottom surface width disposed over the backplane; and
each sub-pixel comprising:
an organic light-emitting diode (OLED) material disposed over the backplane and under the adjacent overhang structures; and
a cathode disposed over the OLED material and under the adjacent overhang structures.

19. The device of claim 18, wherein:
the OLED material is disposed over and in contact with the backplane; and
the cathode is disposed over the OLED material and in contact with the bottom structure.

20. The device of claim 18, further comprising an assistant electrode disposed between the backplane and the plurality of overhang structures.
